(19) United States
(12) Patent Application Publication
(10) Pub. No.: US 2020/0181779 A1
(43) Pub. Date: Jun. 11, 2020

(54) METALIZED POLYURETHANE COMPOSITE AND PROCESS OF PREPARING THE SAME

(71) Applicant: DOW GLOBAL TECHNOLOGIES LLC, Midland, MI (US)

(72) Inventors: Huan Chen, Beijing (CN); Bin Cao, Beijing (CN)

(73) Assignee: Dow Global Technologies LLC, Midland, MI (US)

(21) Appl. No.: 16/312,583

(22) PCT Filed: Jun. 24, 2016
(86) PCT No.: PCT/CN2016/087010

§ 371 Date: Dec. 21, 2018

(51) Int. Cl. C23C 28/02; C08G 18/42; C08K 3/34; C08K 3/04; C08K 3/40; C08K 7/06; C08K 7/14; C08K 13/04; H05K 9/00; C23C 18/38; C25D 3/46; C25D 5/56

(52) U.S. Cl. CPC C23C 28/023; C08G 18/42; C08K 3/34; C08K 3/04; C08K 3/40; C25D 5/56; C08K 7/14; C08K 13/04; H05K 9/0081; C23C 18/38; C25D 3/46; C08K 7/06

(57) ABSTRACT

A metalized polyurethane composite, a process for preparing the metalized polyurethane composite, and a radio frequency filter comprising the metalized polyurethane composite.

### FIELD OF THE INVENTION

The present invention is related to a metalized polyurethane (PU) composite and a process of preparing the same.

### INTRODUCTION

There is a trend in the industry to move electronics from a base station to the top of the cell tower of such base station (that is, tower-top electronics). It is expensive to install and maintain antennas and radio remote heads on cell towers. Therefore, there is a need for light weight infrastructure of the cell tower and associated equipment. A radio frequency (RF) filter is a key component in a remote radio head (RRH) device.

RF cavity filters are commonly used RF filters. A common practice to make these filters is to die cast aluminum into the desired structure or machine a final geometry from a die cast pre-form. It is known that the current die cast aluminum technology is energy intensive, for example, the processing temperature of more than 700° C., and about 7500 British Thermal Unit (BTU)/cubic inches as disclosed in Reaction Injection Molding, Walter E. Becker, Ed., Van Nostrand-Reinhold, New York, 1979, 316 pp. In addition, the aluminum density of the die cast aluminum filters is about 2.7 g/cm³ and part manufacturing requires time-consuming post machining due to the complex geometry of the cavity duplexer filter requiring die tooling with finite die lifetime and intensive labor.

One critical parameter for RF cavity filter performance is the cavity dimensional stability of the RF cavity filter in outdoor conditions (for example, from about −50° C. to about 85° C.). A high coefficient of thermal expansion (CTE) filter housing material is less desirable as compared to a low CTE filter housing material because with temperature fluctuations in the environment surrounding the filter body housing, the higher CTE material can have larger changes in the shape and size of the cavities in the body housing sufficient to alter the filtering frequency of the RF cavity filter from its target value. Another important requirement for RF cavity filter performance is the quality of metal plating on the surface of the filter body housing material. RF waves mainly travel on the surface of the plated metal layer within the skin depth. Therefore, any defects on the plated metal layer would cause interference with RF waves and would destroy or detrimentally affect RF filtering performances.

Attempts have been made to reduce the weight of RF filters. One approach is to use light-weight low-thermal-expansion polymer foams for radio frequency filtering applications. However, metal plating on polymer foams usually result in coarse metal layers. To address this problem, epoxy resins have recently been introduced to reduce the process energy consumption and the density of RF filters, but the manufacturing temperature of epoxy resins is still less satisfactory. The curing temperature of an epoxy system comprising an anhydride acid curing agent is typically in the range of from 140° C. to 160° C., and the gel time at such curing temperature is usually about 20 to 30 minutes.

Therefore, there remains a need to provide a resin system affording lower density than aluminum and energy economy while maintaining acceptable CTE and performance close to that of incumbent materials.

### SUMMARY OF THE INVENTION

The present invention provides a novel metalized polyurethane composite that is suitable for RF filter applications, a process of preparing the same, and a radio frequency (RF) filter comprising the metalized polyurethane composite.

In a first aspect, the present invention provides a process of preparing a metalized polyurethane composite. The process comprises:

(i) providing a polyurethane composite formulation comprising: a polyol, an isocyanate, a fiber, and a moisture scavenger;

(ii) curing the polyurethane composite formulation to form a polyurethane substrate, wherein the polyurethane substrate has a density reduction <15% of that of the polyurethane composite formulation; and

(iii) depositing at least a first layer of metal onto at least a portion of the surface of the polyurethane substrate.

In a second aspect, the present invention provides a metalized polyurethane composite prepared by the process of the first aspect.

In a third aspect, the present invention provides a radio frequency filter comprising the metalized polyurethane composite of the second aspect.

### DETAILED DESCRIPTION OF THE INVENTION

The polyurethane composite formulation useful in the present invention may comprise one or more polyols. The polyols useful in the present invention may include, for example, a polyether polyol or a polyester polyol. The polyols may have a petroleum based building block such as propylene oxide, ethylene oxide, and/or butylenes oxide; or a natural oil derived building block or even specialty polyols such as castor oil polyol; polybutadiene polyol, polytetrahydrofuranpolyol, polycarbonate polyol and caprolactone-based polyol. Examples of commercially available polyols include propylene oxide based polyether polyols available under the tradename VORANOL available from The Dow Chemical Company.

In one embodiment, the polyols useful in the present invention comprise one or more polyester polyols. The polyester polyol may have an average weight molecular weight of from 100 to 10,000, from 200 to 2,000, or from 300 to 500, as measured by GPC with polystyrene standard. The polyester polyol may be present, based on the total weight of the polyols, in an amount of from 0 to 100% by weight, 50% by weight or more, 80% by weight or more, or even 90% by weight or more.

In one embodiment, the polyols useful in the present invention include one or more cardanol-modified epoxy (CME) polyols. The CME polyols may have a hydroxyl (OH) number of from 40 to 200 mgKOH/g, from 80 to 150 mgKOH/g, or from 100 to 130 mgKOH/g. The OH number herein may be measured by titration using KOH. The CME polyols, their characteristics, and their preparation are described, for example, in WO2015077944A1, which is incorporated herein by reference. The CME polyols can be a reaction product of a mixture that includes an epoxy component comprising an epoxy resin and an epoxy-reactive component comprising a cardanol component, and optionally a phenol or phenol derivative component. A ratio of epoxy groups in the epoxy component to the epoxy reactive groups in the epoxy-reactive component may be from 1:0.95 to 1:5. The general formula of typically CME polyols useful in the present invention is shown in formula (I),

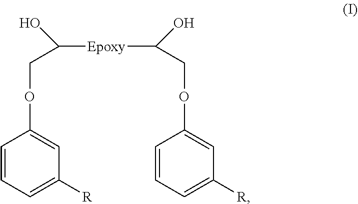

wherein R groups in formula (I) are each independently equal to C₁₅H₃₁₋ₙ (in which n=0, 2, 4 or 6) or C₁₇H₃₃₋ₙ (in which n=0, 2 or 4). In particular, R groups are each independently a saturated or unsaturated straight alkyl chain that includes 15 or 17 carbon atoms. The CME polyol may be derived from a cardanol mixture that variously includes cardanols having different R group. The Epoxy in formula (I) is the epoxy resin derived backbone.

The epoxy resins in the epoxy component useful for the preparation of the CME polyols may include epoxides described in Pham et al., Epoxy Resins in the Kirk-Othmer Encyclopedia of Chemical Technology; John Wiley & Sons, Inc.: online Dec. 4, 2004 and in the references therein; in Lee et al., Handbook of Epoxy Resins, McGraw-Hill Book Company, New York, 1967, Chapter 2, pages 257-307 and in the references therein; May, C. A. Ed. Epoxy Resins: Chemistry and Technology, Marcel Dekker Inc., New York, 1988 and in the references therein; and in U.S. Pat. No. 3,117,099; all which are incorporated herein by reference. Particularly suitable epoxy resins may be based on reaction products of polyfunctional alcohols, polyglycols, phenols, cycloaliphatic carboxylic acids, aromatic amines, or aminophenols with epichlorohydrin. Other suitable epoxy resins may include reaction products of epichlorohydrin with o-cresol and epichlorohydrin with phenol novolacs.

The epoxy resin useful for the preparation of the CME polyols may include those commercially available from The Dow Chemical Company under tradenames D.E.R. and D.E.N. Preferred epoxy resins include bisphenol A diglycidyl ether, tetrabromobisphenol A diglycidyl ether, bisphenol F diglycidyl ether, resorcinol diglycidyl ether, triglycidyl ethers of para-aminophenols, or mixtures thereof.

In one embodiment, the synthesis of a CME polyol using a bisphenol A based diepoxide resin and the cardanol component that has at least mono-unsaturated cardanol, includes the following reaction stage,

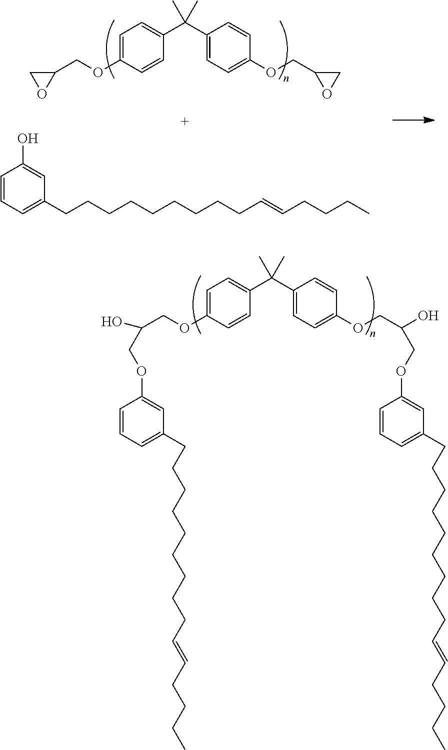

The cardanol component in the epoxy-reactive component for forming the CME polyols may include a cardanol component that is a by-product of cashew nut processing. The cardanol component may comprise a cardanol content of at least 85% by weight or from 85% to 100% by weight, based on the total weight of the cardanol component. The cardanol component includes cardanol as a primary component and may additionally include cardol, methylcardol, and/or anacardic acid as secondary components. The cardanol component may be subjected to a heating process (e.g., at the time of extraction from the cashew nut), a decarboxylation process, and/or a distillation process. Synthesis of the CME polyols includes a reaction between cardanol in the cardanol component and an opened epoxy resin produced from a ring-opening reaction of the epoxy resin in the epoxy component. For example, the CME polyol includes a cardanol linkage with the ring opened epoxy resin, which results in an ether bond between the opened epoxy resin and cardanol.

The polyols useful in the present invention may include phenols derived from a cashew nut shell liquid (CNSL), in which the ratio between cardanol and cardol is in the range of 2.5 to 1.5 or from 2.0 to 1.25. The cardanol and cardol mixture material can be a by-product of cashew nut processing, obtained by distillation of the CNSL via a heating process (for example, at the time of extraction from the cashew nut), a decarboxylation process, and/or a distillation process, such that the CNSL may include cardanol as a primary component and may additionally include cardol, methylcardol, and/or anacardic acid. The above mixture material may comprise different unsaturated long-chain phenols and di-phenols such as benzenediol, cresol, nonyl phenol, butyl phenol, dodecyl phenol, a naphthol based compound, a phenylphenol based compound, a hexachlorophene based compound, or mixtures thereof. The phenols derived from CNSL may be present, based on the total weight of the polyols, in an amount of from 0 to 50% by weight, from 5% to 40% by weight, or from 10% to 30% by weight.

In one embodiment, the polyols include one or more polyether polyols, preferably glycerin initiated short polyether polyols having an average weight molecular weight of less than about 500 as measured by GPC with polystyrene standard. The short polyether polyol may have a functionality >2. The short polyether polyols may include commercially available polyols such as VORANOL CP260 and VORANOL CP450 both available from The Dow Chemical Company, or mixtures thereof. The polyether polyol may be present, based on the total weight of the polyols, in an amount of from 0 to 100% by weight, from 5% to 50% by weight, or from 10% to 25% by weight.

The polyols useful in the present invention may include castor oil as an optional element in the polyurethane composite formulation. The castor oil can increase hydrophobicity and reduce the viscosity of the polyurethane composite formulation. The castor oil may be present, based on the total weight of the polyols, in an amount of from 0 to 50% by weight, from 5% to 40% by weight, or from 10% to 30% by weight.

The polyurethane composite formulation useful in the present invention further comprises one or more isocyanates to react and cure with the polyols to acquire polyurethane resins (that is, a cured polyurethane substrate). “Isocyanate” refers to any compound, including polymers, that contains at least one isocyanate group such as monoisocyanates and polyisocyanates, which are reactive with the polyols. The polyisocyanates typically have an average of two or more, preferably an average of 2.5-4.0, isocyanate groups/molecule.

The isocyanate useful in the present invention may be aromatic, aliphatic, cycloaliphatic, or mixtures thereof. Examples of suitable isocyanates include diphenylmethane diisocyanate (MDI), toluene diisocyanate (TDI), m-phenylene diisocyanate, p-phenylene diisocyanate (PPDI), naphthalene diisocyanate (NDI), isophorone diisocyanate (IPDI), hexamethylene diisocyanate (HDI), tetramethylene-1,4-diisocyanate, cyclohexane-1,4-diisocyanate, hexahydrotolylene diisocyanate (all isomers), 1-methoxyphenyl-2,4-diisocyanate, diphenylmethane-4,4′-diisocyanate, diphenylmethane-2,4′-diisocyanate, 4,4′-biphenylene diisocyanate, 3,3′-dimethoxy-4,4′-diphenyl diisocyanate, 3,3′-dimethyldiphenylpropane-4,4′-diisocyanate, and isomers and/or derivatives thereof. The isocyanate may include polymethylene and polyphenylisocyanates (commonly known as polymeric MDI). Examples of commercially available isocyanates include those from The Dow Chemical Company under tradenames ISONATE, PAPI and VORANATE. Preferably, the isocyanate in the polyurethane composite formulation include a polymeric MDI having a viscosity of about 5 to 300 mPa-s at 25° C. as measured by the ASTM D4889 method, an average functionality of from 2.2 to 2.9, and a free isocyanate (NCO) group of 10-35% by weight. Examples of commercially available isocyanates include SPECFLEX™ NS540 available from The Dow Chemical Company (SPECFLEX is a trademark of The Dow Chemical Company).

The polyols and the isocyanates in the polyurethane composite formulation may be used in an amount to afford a certain molar ratio of the isocyanate groups to the hydroxyl groups (Iso:-OH), for example, from 0.5 to 1.5, from 0.8 to 1.4, or from 1.0 to 1.2.

The polyurethane composite formulation useful in the present invention further comprises one or more fibers. The fibers useful in this invention may be selected from synthetic or natural fibers. The fibers may include, for example, glass fibers, glass fabric, glass sheets, carbon fibers, graphite fibers, boron fibers, quartz fibers, aluminum oxide-containing fibers, silicon carbide fibers or silicon carbide fibers containing titanium, or mixtures thereof. Suitable commercially available fibers useful in the present invention may include, for example, organic fibers such as KEVLAR from DuPont; aluminum oxide-containing fibers, such as NEXTEL fibers from 3M; silicon carbide fibers, such as NICALON fibers from Nippon Carbon; glass fiber, such as ADVANTEX fiber from Owens Corning; and silicon carbide fibers containing titanium; or mixtures thereof. The polyurethane composite formulation may comprise one single type of fiber or combination of two or more different types of fibers. Preferred fibers include glass fibers, glass fabric, glass sheets, carbon fibers, or mixtures thereof. The concentration of the fibers may be, based on the total weight of the polyurethane composite formulation, from 0.01% to 70% by weight, from 0.1% to 50% by weight, or from 5% to 10% by weight.

The polyurethane composite formulation useful in the present invention further includes one or more moisture scavengers. Moisture scavengers herein refer to compounds that are used to chemically lock-up any water or moisture. The moisture scavengers may be selected from organic or inorganic moisture scavengers. Examples of suitable moisture scavengers include zeolite, oxazalidine, triethyl orthoformate, CaO, or mixtures thereof. The moisture scavengers may be present in a sufficient amount to provide a cured and porosity-free polyurethane composite. The concentration of the moisture scavenger may be from 0.0001% to 50% by weight, from 1% to 25% by weight, or from 5% to 10% by weight, based on the total weight of the polyurethane composite formulation. A “porosity-free” polyurethane composite means the polyurethane composite, upon curing the polyurethane composite formulation, demonstrates a density reduction less than 15% of that of the polyurethane composite formulation (before curing).

The polyurethane composite formulation useful in the present invention may also include one or more flame retardants. The flame retardants may include inorganic flame retardants such as aluminum trihydroxide, magnesium hydroxide, boehmite, halogenated flame retardants, and non-halogenated flame retardants such as phosphorus-containing materials. The flame retardant may be present, based on the total weight of the polyurethane composite formulation, in an amount of from 0 to 60% by weight, from 5% to 40% by weight, or from 10% to 30% by weight.

The polyurethane composite formulation useful in the present invention may further comprise one or more crosslinkers that can cause crosslinking of the polyurethane composite formulation. Crosslinkers may have at least three isocyanate-reactive groups per molecule and an equivalent weight per isocyanate-reactive group of less than 400. Examples of suitable crosslinkers include diethanol amine, monoethanol amine, triethanol amine, mono- di- or tri(isopropanol) amine, glycerine, trimethylol propane (TMP), pentaerythritol, sorbitol, or mixtures thereof. The crosslinker may be present, based on the total weight of the polyols in the polyurethane composite formulation, in an amount of from 0 to 5% by weight, from 0 to 3% by weight, or from 0.1% to 1.5% by weight.

The polyurethane composite formulation may further include one or more chain extenders. Chain extenders may have two isocyanate-reactive groups per molecule and an equivalent weight per isocyanate-reactive group of less than 400. Examples of suitable chain extenders include amines ethylene glycol, diethylene glycol, 1,2-propylene glycol, dipropylene glycol, tripropylene glycol, ethylene diamine, phenylene diamine, bis(3-chloro-4-aminophenyl)methane and 2,4-diamino-3,5-diethyl toluene. The chain extenders are typically present, by weight based on the total weight of the polyols in the polyurethane composite formulation, in an amount of from 0 to 10%, from 1% to 8%, or from 3% to 5%.

The polyurethane composite formulation useful in the present invention may further comprise one or more curing catalysts based on the different needs of curing time. Examples of suitable curing catalysts include tertiary amines, Mannich bases formed from secondary amines, nitrogen-containing bases, alkali metal hydroxides, alkali phenolates, alkali metal alcoholates, hexahydrothiazines, organometallic compounds, or mixtures thereof. Preferred catalysts include tris(dimethylaminomethyl)phenol, dibutyltin dilaurate, or mixtures thereof. The curing catalyst may be used, based on the total weight of the polyurethane composite formulation, in an amount of from 0 to 10% by weight, from 0.01% to 5% by weight, or from 0.05% to 2% by weight.

The polyurethane composite formulation useful in the present invention may further include optional additives that can be used to beneficially lower the cost of manufacturing the formulation or can be used to modify the physical properties of the formulation. Additives used to modify the physical properties of the resulting polyurethane composite may include, for example, fillers such as inorganic and/or organic fillers, solvents, plasticizers, ultraviolet (UV) stabilizers, perfumants, antistats, insecticides, bacteriostats, fungicides, surfactants, coloring agents, water-binding agents or additional conventional elastomers such as ethylene propylene diene (EPDM) rubber, ethylene propylene rubber (EPR), polysulfide, or mixtures thereof. Generally, the combined content of these additives may be, based on the total weight of the polyurethane composite formulation, from 0 to 60% by weight, from 10% to 60% by weight, or from 25% to 45% by weight.

The polyurethane composite formulation useful in the present invention may be prepared by admixing: the polyol, the isocyanate, the fiber, the moisture scavenger, and other optional components described above such as the curing catalyst. The polyurethane composite formulation can be achieved by blending the above components in any known mixing equipment or reactor vessels. The above components for synthesizing the polyurethane composite formulation can be mixed and dispersed at a temperature enabling the preparation of an effective polyurethane formulation. For example, the temperature for mixing the components may be generally from 0° C. to 30° C. Time for mixing the above components to form the polyurethane composite formulation may be from 10 seconds to about 24 hours, from 60 seconds to 30 minutes, or from 60 seconds to 10 minutes. The preparation of the polyurethane composite formulation may be a batch or a continuous process. The mixing equipment used in the process may be any vessel and ancillary equipment well known to those skilled in the art. The polyurethane composite formulation may have a viscosity in the range of from 1 Pa-s to 100 Pa-s or from 10 Pa-s to 50 Pa-s at room temperature (20-25° C.) as measured by the ASTM D2983 method.

The polyurethane composite formulation useful in the present invention can be cured to form a thermoset or cured composite, i.e., a polyurethane composite. In one embodiment, the polyurethane composite formulation can be reacted to form particularly a polyurethane substrate for use in preparing a metalized polyurethane composite. For example, the polyurethane composite formulation can be cured under conventional processing conditions to form a solid composite.

Curing the polyurethane composite formulation may be carried out at curing reaction conditions including a predetermined temperature and for a predetermined period of time sufficient to cure the polyurethane composite formulation. The curing conditions include, for example, heating the polyurethane composite formulation at a typical processing temperature, generally in the range of from 10° C. to 100° C., from 25° C. to 80° C., or from 60° C. to 80° C. Curing may be carried out generally for a time period, for example, from 10 seconds to 1 day, from 60 seconds to 30 minutes, or from 60 seconds to 10 minutes. The process to cure the polyurethane composite formulation may include vacuum casting, liquid injection molding, reactive injection molding, or resin transfer molding.

The polyurethane composite formulation useful in the present invention can be cured at a lower processing temperature as described above, as compared to an epoxy system comprising an epoxy resin and an anhydride acid curing agent useful for preparing RF filters, where the epoxy system usually requires a curing temperature of from 140° C. to 160° C. In addition, even at the lower processing temperature (for example, at about 100° C. or lower), the polyurethane composite formulation also demonstrates a shorter gel time, for example, in the range of from 60 seconds to 30 minutes or from 60 seconds to 10 minutes, as compared to the epoxy system. Gel time may be determined according to the test method described in the Examples section below.

The polyurethane composite formulation useful in the present invention upon curing forms the polyurethane composite, which can be used as a substrate for reducing the weight and maintaining the low CTE. The obtained polyurethane composite may have a density reduction <15%, 10% or less, 5% or less, or even 1% or less, of that of the polyurethane composite formulation. The polyurethane composite has a density lower than aluminum, for example, from 1.1 g/cm³ to 2.2 g/cm³, from 1.2 to 2.0 g/cm³, or from 1.5 g/cm³ to 1.9 g/cm³. The polyurethane composite may have a CTE less than 40 ppm/° C., 32 ppm/° C. or less, 30 ppm/° C. or less, 28 ppm/° C. or less, or even 25 ppm/° C. or less. Density and CTE may be determined according the test method described in the Examples section below.

In addition, the polyurethane composite can be metal plated, that is, metallization of the polyurethane composite, to form a metalized polyurethane composite. The ability to metal plate a polymer composite is one of the key features useful for RF cavity filter applications in accordance with the present invention. “Metal plateability” herein is defined as the ability to deposit one or more metal layers such as copper, silver or gold to the polymer composite via various plating techniques, which would result in smooth surface and acceptable adhesion of the metal layer to the polymer composite.

The present invention also provides a process of preparing the metalized polyurethane composite. The process comprises: (i) providing the polyurethane composite formulation described above, (ii) curing the polyurethane composite formulation to form the polyurethane substrate, that is, the polyurethane composite described above, and (iii) depositing at least a first layer of metal onto at least a portion of the surface of the polyurethane substrate (that is, metallization of the polyurethane composite). The polyurethane substrate is the polyurethane composite described above which is made from the polyurethane composite formulation. Conditions for preparing and curing the polyurethane composition formulation are as described above. The metalized polyurethane composite may include one or more metal layers, i.e., a mono metal layer or multi metal layers on the polyurethane substrate. In one embodiment, the metal layer of the metalized polyurethane composite is a multilayer comprising a first metal layer and a second metal layer, where the first metal layer can be adhered to at least a portion of the polyurethane substrate, and the second metal layer is deposited on at least a portion of the first metal layer. The polyurethane composite has satisfactory metal plateability. For example, the metalized polyurethane composite obtained from the process of the present invention demonstrates smooth surface as observed by the naked eye. The metal layer and the polyurethane composite in the metalized polyurethane composite can also adhere to each other at an adhesion level of ISO Class 0 as measured by DIN EN ISO2409 or ASTM Class 5B as measured by ASTM D3359.

The metal layer of the metalized polyurethane composite of the present invention may be made of metals including, for example, copper, nickel, silver, zinc, gold, or mixtures thereof. Preferably, the metalized polyurethane composite comprises a layer of copper and/or a layer of silver. Total thickness of metal layers of the metalized polyurethane composite will vary depending on the specific application. For example, for RF filter devices, the total thickness of metal layers may depend on the operation frequency and cavity structure of the RF filter devices made therefrom. For example, the total thickness of the metal layers may be generally from about 0.1 μm to about 50 μm, from about 0.25 μm to about 20 μm, from about 0.25 μm to about 10 μm, or from about 0.25 μm to about 2.5 μm.

The surface of the polyurethane substrate of the metalized polyurethane composite may be deposited by metal in the range of from 10% to 100% or from 30% to 60%. The thickness of the polyurethane substrate of the metalized polyurethane composite can be generally from about 0.5 millimeter (mm) to about 100 mm, from about 1 mm to about 10 mm, or from about 1 mm to about 5 mm.

In general, the process of preparing the metalized polyurethane composite of the present invention includes the step of manufacturing and providing the polyurethane composite substrate followed by depositing a metal layer on at least a portion of the surface of the polyurethane substrate. Plating such as electroless plating or electroplating processes, or a combination of both, can be used to deposit a portion of the surface of the polyurethane substrate or the entire surface of the polyurethane substrate with a metal layer. In one embodiment, the depositing process may include depositing the substrate with successive layers of metal (for example, copper and silver). Other conventional techniques such as spraying or painting could also be used to deposit one or more metal layers on the substrate. In another embodiment, after the above first layer, such as copper, is deposited on the substrate, a second layer of metal, such as silver, can be formed on at least a portion of the first layer by employing another electroplating process. The total thickness of metal plated on the substrate is the same as described in the metalized polyurethane composite section.

Preferably, the process of preparing the metalized polyurethane composite is carried out by initially processing the polyurethane substrate through an appropriate pretreatment process, followed by electroless plating a thin layer (for example, from about 0.25 micron to about 2.5 microns) of metal such as a copper, silver, or nickel. For example, in one embodiment, a layer of copper may be plated on at least a portion of the surface of the polyurethane substrate wherein the layer may be about 1 micron in thickness. The electroless plating may then be followed by plating a metal such as copper to a thickness up to about 20 micron in one embodiment; and thereafter another layer of metal such as silver may optionally be applied by plating to the desired thickness of the layer such as for example about 1 micron. Multiple layers may be used or a single plating layer may be used. Additional metal layers may be conveniently applied over an initial metallization layer by using electroplating techniques or other plating techniques such as electroless deposition or immersion deposition. Typically, electroplating processes are used for the addition of thicker layers, as these processes are fast. In an embodiment where an additional copper layer is desired, the layer could also be added using an electroless process (although deposition rate for the greater thickness may be lower). For an embodiment where a final silver layer is desired, the thickness can be small; and therefore, either electroless or immersion deposition can also be used.

The appropriate pretreatment method for processing the polyurethane substrate may include chemical acid/base etching and physical roughening (for example, sandblasting) treatments. Preferred pretreatment method is a chemical etching method, based on an initial conditioning step in an alkaline, solvent-containing solution, followed by treatment in a hot alkaline solution containing permanganate ion. Residues of the permanganate etch step may be then removed in a neutralization bath, containing an acidic solution of a hydroxylamine compound.

The process of preparing the metalized polyurethane composite described above by a copper or silver plating process on the polyurethane composite from which a high quality metallization layer of copper can be achieved. A high quality metallization layer with reference to a plated composite substrate herein means the substrate to be plated has metal plateability as described above.

The beneficial properties of the polyurethane composite such as a density and a CTE described above may be imparted to the metalized polyurethane composite which, in one embodiment, may be advantageously used in preparing for example RF devices. The metalized polyurethane composite may have a density reduction <15%, 10% or less, 5% or less, or even 1% or less, as compared to that of the polyurethane composite formulation. For example, the metalized polyurethane composite may have a density of from 1.1 g/cm³ to 2.2 g/cm³, from 1.2 to 2.0 g/cm³, or from 1.5 g/cm³ to 1.9 g/cm³. The metalized polyurethane composite may also have a CTE of less than 40 ppm/° C., 32 ppm/° C. or less, 30 ppm/° C. or less, 28 ppm/° C. or less, or even 25 ppm/° C. or less. Density and CTE may be determined according the test method described in the Examples section below.

The metalized polyurethane composite of the present invention can be used in various applications, particularly for use in telecommunication devices. Telecommunication is any transmission, emission or reception of signs, signals, writings, images and sounds or intelligence of any nature by wire, radio, optical or other electromagnetic systems. Telecommunication device may include, for example, tower-top electronics such as wireless filters and RF devices. Preferably, the metalized polyurethane composite is used in RF filters.

The present invention also provides a RF filter, preferably a RF cavity filter, comprising the metalized polyurethane composite described above, as one component. RF filters are incorporated, for example, into tower-top electronics, such as wireless filter applications. RF filters, their characteristics, their fabrication, their machining, and their overall production are described, for example, in U.S. Pat. No. 8,072,298, which is incorporated herein by reference, describes a method for producing a RF filter and how to integrate the layers required for a RF filter with each other to form the RF filter. For example, the RF filter includes a housing body with other components known in the art to provide a functional RF cavity filter. For example, the body housing can further include a cover plate fastened to the body housing that encloses resonating cavities of the body housing. One skilled in the art would be familiar with other components that the body housing could have to facilitate the operation of the RF filter. In general, the process used to manufacture RF filters includes, for example, a process step of forming a RF filter body housing from the polyurethane composite described above. The process further includes a step of coating the body housing with an electrically conductive material (e.g. metal) to form the metalized polyurethane composite described above.

### EXAMPLES

Some embodiments of the invention will now be described in the following Examples, wherein all parts and percentages are by weight unless otherwise specified. The following materials are used in the examples:

Various terms, designations and materials used in the examples are as follows:

TABLE 1

| Raw material | Function | Feature | Supplier |
|---|---|---|---|
| VORANOL CP 260 | Polyol | Polyether polyol | The Dow Chemical Company |
| Polyol | | | |
| C383 Polyol | Polyol | CME polyol | Self-preparation |
| RAYNOL PS 3152 | Polyol | Polyester polyol | Raynol |
| CNSL 6336 | Phenol | CNSL comprising 63% | Hua Da SaiGao (Beijing) |
| | | cardanol and 36% cardol | Technology |
| Castor Oil | Polyol | Natural oil derived | Sinopharm |
| | | polyol | |
| VORAPEL T5001 | Polyol | Polyether polyol | The Dow Chemical Company |
| Glycerin | Crosslinker | | Sinopharm |
| Zeolite | Moisture | Molecular sieves | Grace |
| | scavenger | | |
| BYK A530 | Defoamer | | BYK |
| BYK W9076 | Defoamer | | BYK |
| BYK P9920 | Defoamer | | BYK |
| SPECFLEX NS540 | Isocyanate | Isocyanate | The Dow Chemical Company |
| NF 200 | Filler | Wollastonite | Xinyu Nanfang |
| Sibond S602 | Filler | Silica | Sibelco |
| ATH | Filler | Aluminum hydroxide | Shandong Shibang |
| CarboNXT 80 | Filler | Carbon fiber | Marubeni |
| STW-400 | Filler | Glass fiber | STW |

The following standard analytical equipment and methods are used in the Examples:

### Gel Time Test

A hot plate (100° C.) was used to determine the gel time of a formulation. 1 mL sample of the formulation was spread to form a 5 cm×5 cm square on the hot plate and time was recorded as the starting time. The time period till the sample started to form continuous gelation without break was recorded as the endpoint of the gel time.

### Density Measurement

The density of a polyurethane (PU) composite sample was tested by Archimedes drainage method. The sample was weighted before merging into water, and the weight of sample in air was recorded as W 1. Then after completely merging the sample to water, the weight of sample in water was recorded as W2. The density was calculated as, Density=W1/(W1−W2).

### CTE Measurement

The CTE was measured using a Thermomechanical Analyzer (TMA Q500 from TA Instruments) on plaque samples with an approximate thickness of 5 mm. An expansion profile was generated using a heating rate of 10° C. per minute (° C./min), and the CTE was calculated as the slope of the expansion profile over the temperature range of from 50° C. to 80° C. The CTE was calculated as follows:

CTE=ΔL/(ΔT*L),

where ΔL is the change in sample length (μm), L is the original length of the sample (meter) and ΔT is the change in temperature (° C.).

### Adhesion Test

The adhesion performance of plating layers to a substrate was tested by the cross-cut method according to the DIN EN ISO 2409 method and ASTM D3359-2009 method, respectively. Two series of parallel cuts cross angled to each other to obtain a pattern of 100 similar squares in 1 mm spacing. The pattern was evaluated by using a table chart after a short treatment with a stiff brush, and then applying an adhesive tape. Rating being Class 0 of ISO DIN EN ISO 2409 or Class 5B of ASTM D3359 is acceptable.

### Flame Retardancy Test

The flame retardancy (FR) test was conducted in accordance with Underwriters Laboratories Inc. UL 94 standard for safety “Tests for Flammability of Plastic Materials for Parts in Devices and Appliances”. Samples with 6 mm thickness were used for the vertical burn test and the time of fire extinguishing was recorded. Samples passing UL-V0 rating are acceptable.

### T_{g} Measurement

T_{g} was measured by differential scanning calorimetry (DSC) according to the ISO 11357-2 method. A 5-10 milligram (mg) sample was analyzed in an open aluminum pan on a TA Instrument DSC Q2000 fitted with an auto-sampler under nitrogen atmosphere. T_{g} measurement by DSC was with 20-140° C., 20° C./min (1^{st} cycle), and 20-140° C., 20° C./min (2^{nd} cycle). T_{g} was obtained from the 2^{nd} cycle.

### Preparation of C383 Polyol

D.E.R. 383 resin (182 grams, available from The Dow Chemical Company, an aromatic epoxy resin that is a reaction product of ephichlorohydrin and bisphenol A) and CNSL 94 (330 grams, available from Hua Da SaiGao (Beijing) Technology, a cashew nutshell liquid containing 94% by weight of cardanol) were added in a flask protected with N₂. The ratio of epoxy groups in the D.E.R 383 resin to epoxy reactive hydroxyl groups in the CNSL was approximately 1:2.2. Catalyst A (0.26 gram, 70% by weight ethyltriphenylphosphonium acetate in methane) was added, and then the resulting mixture was heated to 160° C. and maintained for four hours. Finally, the C383 polyol was obtained and cooled to 40° C.

### Preparation of Polyurethane Composites

Materials of the polyurethane composite formulations described in Table 2 were mixed using a FlackTek speed mixer at 2,500 revolutions per minute (rpm) for 1 minute (min). The resulting mixture was then transferred into a parallel glass mold for forming a 5 mm thick plate sample. The sample was then sent to a curing oven and heated at a temperature of 100° C. for 4 hours. Properties of the polyurethane composite formulations and the obtained polyurethane composites (PUC-1, PUC-2, PUC-3, PUC-A, PUC-B and PUC-C) were measured according to the test methods described above and results are given in Tables 2 and 3.

TABLE 2

| Raw material of PU composite | PU composite formulation | | | | | |
|---|---|---|---|---|---|---|
| formulation, % by weight | PUC-1 | PUC-2 | PUC-3 | PUC-A | PUC-B | PUC-C |
| VORANOL CP 260 polyol | 6.17 | | | 6.16 | 6.16 | |
| PS3152 polyester polyol | | 17.46 | | | | |
| C383 polyol | 3.74 | | | 3.74 | 3.74 | |
| CNSL 6336 | 3.58 | | | 3.58 | 3.58 | |
| Castor Oil | 2.98 | | | 2.98 | 2.98 | |
| VORAPEL T5001 | | | 18.45 | | | 18.55 |
| Glycerin | 0.99 | 0.95 | 0.90 | 0.99 | 0.99 | 0.91 |
| SPECFLEX NS540 | 19.89 | 18.98 | 18.08 | 19.88 | 19.88 | 18.18 |
| Zeolite | 0.99 | 0.95 | 0.90 | | 1.00 | |
| BYK A530 | 0.04 | 0.04 | 0.04 | 0.04 | 0.04 | 0.04 |
| BYK W9076 | 0.12 | 0.11 | 0.11 | 0.12 | 0.12 | 0.11 |
| BYK P9920 | 0.50 | 0.47 | 0.45 | 0.50 | 0.50 | 0.45 |
| Sibond S602 | | | | 62.01 | 41.01 | |
| NF 200 | 35.80 | 35.86 | 36.17 | | | 36.73 |
| ATH | 20.09 | 20.11 | 20.07 | | 20.00 | 20.18 |
| CarboNXT | 5.11 | 5.07 | | | | |
| STW-400 | | | 4.83 | | | 4.85 |
| Total weight | 100.00 | 100.00 | 100.00 | 100.00 | 100.00 | 100.00 |
| Properties | | | | | | |
| Density of PU composite | 1.9 | 1.9 | 1.95 | 1.8 | 1.85 | 1.9 |
| formulation (g/cm³) | | | | | | |
| Typical processing temperature | ~100 | ~100 | ~100 | ~100 | ~100 | ~100 |
| (TPT, ° C.) | | | | | | |
| Gel time under TPT (min) | 1~5 | 1~5 | 1~5 | 1~5 | 1~5 | 1~5 |

The results summarized in Table 3 illustrate that the polyurethane composite formulations had a typical processing temperature of about 100° C. and a gel time of about 1-5 min under such processing temperature. In addition, the results showed that the density of PUC-1, PUC-2 and PUC-3 composites was 1.9 g/cm³, which is 30% lower than aluminum RF filters. Furthermore, the CTEs of the PUC-1, PUC-2 and PUC-3 composites were around 24 to 38 ppm/° C., which is similar to aluminum. In contrast, the PUC-A composite demonstrated undesirably high CTE (about 53 ppm/° C.). The PUC-B and PUC-C composites were not porosity free.

TABLE 3
Properties of polyurethane composites

| PU Composite | PUC-1 | PUC-2 | PUC-3 | PUC-A | PUC-B | PUC-C |
|---|---|---|---|---|---|---|
| FR UL-V0 rating | Pass | Pass | Pass | Fail | Pass | Pass |
| T_{g} (° C.) | 98.25 | 76.81 | 71.17 | 93.04 | 95.68 | 74.99 |
| Density of PU composite | 1.9 | 1.9 | 1.9 | <1.0 | | <1.0 |
| (g/cm³) | | | | | | |
| Porosity Free | Yes | Yes | Yes | No | Yes | No |
| CTE of PU composite | 30.70 | 24.16 | 37.83 | 53.12 | 54.87 | 37.90 |
| (ppm/° C.) | | | | | | |

### Examples (Exs) 1-3 and Comparative (Comp) Exs A-C Metallization of PU Composites

The polyurethane composites as prepared were cut using a water saw to obtain non-metalized plates with a desired size, for example, a series of plate samples measuring 5 cm×5 cm were prepared for use in the Examples herein.

The plate samples obtained above were metalized according to a metallization process as follows, (1) processing the plate sample through an appropriate pretreatment process; (2) electroless plating a first thin layer (about 1 micron) of metal (e.g., copper) on the pretreated sample plate; and then (3) electroplating another second metal (e.g., silver) onto the first metal up to a thickness of up to about 5 microns. Details of a process flow were described in more details in Table 4. Properties of the obtained metalized PU composites are given in Table 5.

TABLE 4
Plating Procedure on PU Composites

| | | | | | Post |
|---|---|---|---|---|---|
| | | | Temperature | Time | Rinse |
| Step | Product | Chemicals (vol %) | (° C.) | (min) | (min) |
| 1 | Sweller | 11.5% CUPOSIT ™ Z Solution + 12.5% | 80 | 10 | 3 |
| | | CIRCUPOSIT ™ MLB Conditioner 211 | | | |
| 2 | Oxidizer | 15% CUPOSIT Z Solution + 10% | 80 | 20 | 3 |
| | | CIRCUPOSIT MLB Promoter 213A-1 | | | |
| 3 | Neutralizer | 5% CIRCUPOSIT MLB Neutralizer 216-5 | 40 | 5 | 3 |
| 4 | Sweller | 11.5% CUPOSIT Z Solution + 12.5% | 80 | 10 | 3 |
| | | CIRCUPOSIT MLB Conditioner 211 | | | |
| 5 | Oxidizer | 15% CUPOSIT Z Solution + 10% | 80 | 20 | 3 |
| | | CIRCUPOSIT MLB Promoter 213A-1 | | | |
| 6 | Neutralizer | 5% CIRCUPOSIT MLB Neutralizer 216-5 | 40 | 5 | 3 |
| 7 | Conditioner | 3% CIRCUPOSIT Conditioner 233 | 40 | 5 | 4 |
| 8 | Microetch | 2% H₂SO₄ + 100 g/l Sodium persulfate | 22 | 1 | 3 |
| 9 | Predip | 250 g/l CATAPREP ™ 404 Pre-Dip | 22 | 1 | None |
| 10 | Catalyst | 250 g/l CATAPREP ™ 404 Pre-Dip + 2% | 40 | 5 | 2 |
| | | CATAPOSIT ™44 Catalyst Concentrate | | | |
| 11 | Electroless | CIRCUPOSIT 253A Electroless Copper | 46 | 20 | 2 |
| | Copper | 5% 253A + 1% 253E with 8 g/l NaOH, 10 | | | |
| | | g/l formaldehyde | | | |
| 12 | Electrolytic | To 5 micron deposit thickness | | | 2 |
| | Silver | | | | |

Note:
CUPOSIT ™ Z Solution, CIRCUPOSIT ™ MLB Conditioner 211, CIRCUPOSIT MLB Promoter 213A-1, CIRCUPOSIT MLB Neutralizer 216-5, IRCUPOSIT Conditioner 233, CATAPREP ™ 404 Pre-Dip, CATAPOSIT ™44 Catalyst Concentrate, and CIRCUPOSIT 253A Electroless Copper are all available from The Dow Chemical Company (CUPOSIT, CIRCUPOSIT, CATAPREP and CATAPOSIT are trademarks of The Dow Chemical Company).

As shown in Table 5, a plating process on the polyurethane composites PUC-1, PUC-2 and PUC-3 of the present invention resulted in metalized polyurethane composite plates that had smooth surfaces (Exs 1-3). In contrast, the comparative metalized polyurethane composites (Comp Exs A and C) demonstrated coarse plating surfaces. Table 5 also shows the adhesion test results of the metalized polyurethane composite plates of Exs 1-3, where the edges of the cuts were completely smooth and none of the squares of the lattice was detached in the adhesion tests. The adhesion level of the metal layers to the polyurethane composites in the metalized polyurethane composite plates of Exs 1-3 all met Class 0 rating of ISO DIN EN ISO 2409 and Class 5B rating of ASTM D3359.

TABLE 5

| | Prorerties of Metalized PU Composite | | | | | |
|---|---|---|---|---|---|---|
| | | | | Comp | Comp | Comp |
| | Ex 1 | Ex 2 | Ex 3 | Ex A | Ex B | Ex C |
| PU | PUC-1 | PUC-2 | PUC-3 | PUC-A | PUC-B | PUC-C |
| composite | | | | | | |
| Surface of | Smooth | Smooth | Smooth | Coarse | Smooth | Coarse |
| metalized | | | | | | |
| PU | | | | | | |
| composite | | | | | | |
| Adhesion | ISO Class | ISO Class | ISO Class | ISO Class | ISO Class | ISO Class |
| test | 0/ASTM | 0/ASTM | 0/ASTM | 0/ASTM | 0/ASTM Class | 0/ASTM |
| | Class 5B | Class 5B | Class 5B | Class 5B | 5B | Class 5B |

1. A process of preparing a metalized polyurethane composite, comprising:
(i) providing a polyurethane composite formulation comprising: a polyol, an isocyanate, a fiber, and a moisture scavenger;
(ii) curing the polyurethane composite formulation to form a polyurethane substrate, wherein the polyurethane substrate has a density reduction <15% of that of the polyurethane composite formulation; and
(iii) depositing at least a first layer of metal onto at least a portion of the surface of the polyurethane substrate.

2. The process of claim 1, wherein the polyol comprises a polyester polyol.

3. The process of claim 1, wherein the moisture scavenger is selected from zeolite, oxazalidine, triethyl orthoformate, CaO, or mixtures thereof.

4. The process of any one of claims 1-3, wherein the polyurethane composite formulation comprises from 0.0001% to 50% by weight of the moisture scavenger, based on the total weight of the polyurethane composite formulation.

5. The process of any one of claims 1-3, wherein the fiber is selected from a glass fiber, a carbon filer, or mixtures thereof.

6. The process of any one of claims 1-3, wherein the polyurethane composite formulation comprises from 0.01% to 70% by weight of the fiber, based on the total weight of the polyurethane composite formulation.

7. The process of any one of claims 1-3, wherein the polyurethane composite formulation further comprises a flame retardant.

8. The process of any one of claims 1-3, wherein the polyurethane substrate has a density of from 1.1 g/cm³ to 2.2 g/cm³ and a coefficient of thermal expansion of less than 40 ppm/° C.

9. The process of any one of claims 1-3, further comprising the step of depositing at least a second layer of metal onto at least a portion of the first layer of metal.

10. The process of any one of claims 1-3, wherein the depositing step is carried out by an electroless plating process, an electroplating process, or a combination thereof.

11. A metalized polyurethane composite prepared by the process of any one of claims 1-10.

12. A radio frequency filter comprising the metalized polyurethane composite of claim 11.
